(19) United States
(12) Patent Application Publication
(10) Pub. No.: US 2008/0123874 A1
(43) Pub. Date: May 29, 2008

(54) Audio amplifier system

(75) Inventor: Chia-Wang Chiu, Taipei County (TW)

Correspondence Address: BIRCH STEWART KOLASCH & BIRCH, PO BOX 747, FALLS CHURCH, VA, 22040-0747, US

(73) Assignee: GIGA-BYTE TECHNOLOGY CO., LTD.

(21) Appl. No.: 11/604,732

(22) Filed: Nov. 28, 2006

(51) Int. Cl. H03F 21/00

(52) U.S. Cl. 381/120

(57) ABSTRACT

An audio amplifier system. The power supply includes a plurality of power lines. The mainboard includes a first voltage input connector coupled to one of the power lines receiving a first power supply, and an audio output signal connector outputting a first audio output signal. The audio amplifier module located on a chassis includes a second voltage input connector coupled to the others receiving a second power supply, an audio input signal connector coupled to the audio output signal connector via a cable receiving the first audio output signal, and an amplifier circuit amplifying the first audio output signal into a second audio output signal.

### BACKGROUND OF THE INVENTION

1. Field of the Invention

The invention relates to a computer system, and in particular to a system of an audio amplifier module in a computer system.

2. Description of the Related Art

Music in a computer system is output to earphone or speakers by a soundcard. The soundcard may be embedded on a mainboard or a separate soundcard connected to the mainboard by a PCI slot. The earphone and the speakers output the music via attachment to an output jack of the soundcard.

However, the soundcard can only drive low power speakers. Home theater speakers with 2 to 7.1 sound channels may be driven by an audio amplifier attached to the speaker jack of the soundcard, wherein each sound channel may drive a speaker with power between 10 and 100 W or higher.

Home theater speakers with 2 to 7.1 sound channels can be driven by a conventional computer system, but only when the system is equipped with an audio amplifier. What is called for is a computer system to drive home theater speakers.

### BRIEF SUMMARY OF INVENTION

Audio amplifier systems are provided. An exemplary embodiment of an audio amplifier system comprises a power supply having a plurality of power lines providing power, a mainboard comprising a first voltage input connector coupled to one of power lines receiving power from a first power source, an audio output signal connector outputting a first audio output signal, an audio amplifier module located on a chassis, comprising a second voltage input connector coupled to one of power lines receiving power from a second power source, an audio input signal connector coupled to the audio output signal connector via a cable receiving the first audio output signal, and an amplifier circuit amplifying the first audio output signal into a second audio output signal.

Another exemplary embodiment of an audio amplifier system comprises a power supply having a plurality of power lines for providing power, a mainboard comprising a first voltage input connector coupled to one of power lines receiving power from a first power source, an audio output signal connector outputting a first audio output signal, an audio amplifier module comprising an audio amplifier module card or an audio amplifier module box, comprising a second voltage input connector coupled to another of the power lines receiving power from a second power source, an audio input signal connector coupled to the audio output signal connector via a cable receiving the first audio output signal, and an amplifier circuit amplifying the first audio output signal into a second audio output signal.

### BRIEF DESCRIPTION OF DRAWINGS

The invention can be more fully understood by reading the subsequent detailed description and examples with references made to the accompanying drawings, wherein:

FIG. 1 is a schematic view of audio amplifier system 100 of the invention.

FIG. 2A is a schematic view of audio amplifier system 200 of the invention.

FIG. 2B is a schematic view of audio amplifier module card 220 of the invention.

FIG. 3A is a schematic view of audio amplifier system 300 of the invention.

FIG. 3B is a schematic view of audio amplifier module box 320 of the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

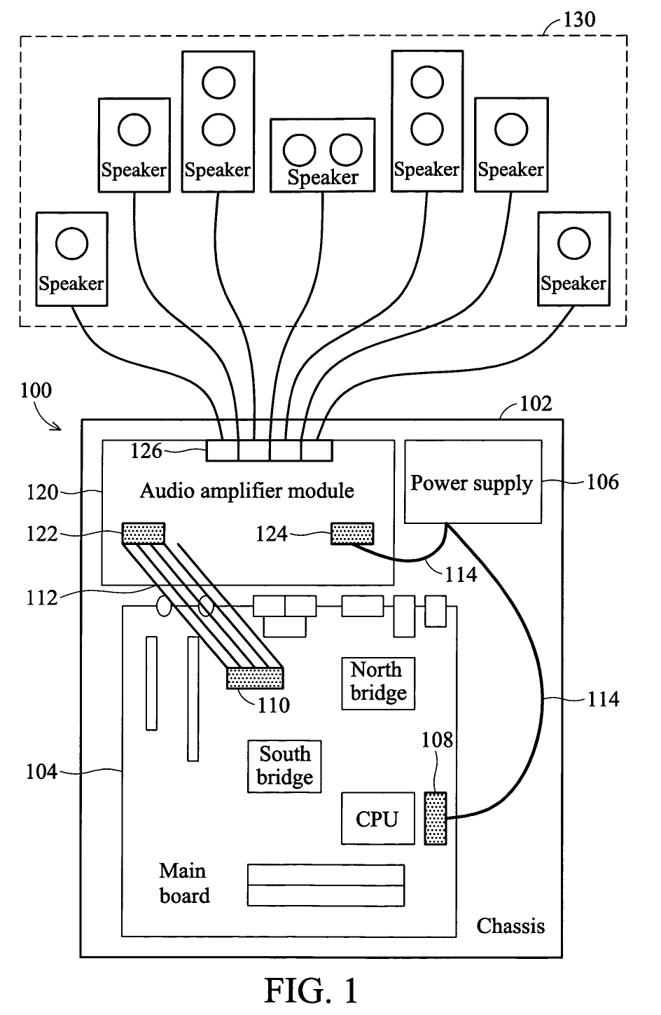

FIG. 1 is a schematic view of audio amplifier system 100 according to an embodiment of the invention, comprising mainboard 104, power supply 106 and audio amplifier module 120 disposed on chassis 102.

Power supply 106 comprises a plurality of power lines 114. Note that power supply 106 provides 5V, 12V, and ground voltage, and power line 114 is a 4-pin power line.

Mainboard 104 comprises voltage input connector 108 and audio output signal connector 110. Voltage input connector 108 is coupled to one of power lines 114 receiving 5V, 12V, and ground voltages from power supply 106, powering mainboard 104. Audio output signal connector 110 outputs a first audio output signal, which can be AC97, high definition, Dolby or digital theater system audio, and audio output signal connector 110 can be an AC97, high definition, Dolby or digital theater system audio output signal connector.

Audio amplifier module 120 comprises voltage input connector 124 and audio input signal connector 122. Voltage input connector 124 is coupled to one of power lines 114 receiving 5V, 12V, and ground voltages from power supply 106 powering audio amplifier module 120. Audio input signal connector 122 is coupled to audio output signal connector 110 via cable 112 receiving the first audio output signal. An amplifier circuit amplifies the first audio output signal into a second audio output signal. Audio input signal connector 122 can be an AC97, high definition, Dolby or digital theater system audio output signal connector, and the second audio output signal can be an AC97, high definition, Dolby or digital theater system audio output signal. The power of the amplifier circuit is between 10 and 100 W or more than 100 W.

Moreover, audio amplifier module 120 further comprises speaker output connector 126 coupled to and outputting the second audio output signal through speakers 130, home theater speakers with high-output power. Speaker output connector 126 comprises 2 to 7.1 sound channels, each of which can drive 10 to 100 W or more than 100 W.

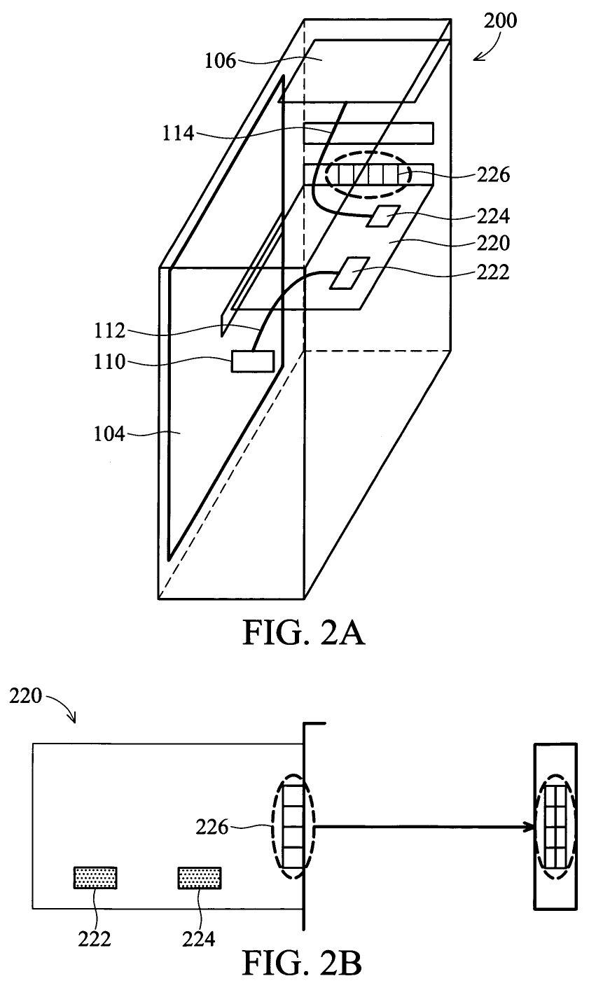

FIG. 2A is a schematic view of audio amplifier system 200 according to an embodiment of the invention. In this embodiment, the audio amplifier module is implemented by audio amplifier module card 220. Audio amplifier system 200 differs from audio amplifier system 100 only in that the audio amplifier module card is compatible with a peripheral controller interface (PCI), an accelerated graphics port (AGP) and a PCIE slot.

FIG. 2B is a schematic view of audio amplifier module card 220 according to an embodiment of the invention. Audio amplifier module card 220 comprises voltage input connector 224, audio input signal connector 222 and speaker output connector 226.

Voltage input connector 224 is coupled to one of power lines 114 receiving 5V, 12V, and ground voltages from power supply 106 powering audio amplifier module card 220. Audio input signal connector 222 is coupled to audio output signal connector 110 via cable 112 receiving the first audio output signal. The amplifier circuit amplifies the first audio output signal into the second audio output signal. Audio input signal connector 222 can be an AC 97, high definition, Dolby, or digital theater system audio output signal connector, and the second audio output signal can be an AC 97, high definition, Dolby, or digital theater system audio output signal. The power of the amplifier circuit is between 10 and 100 W or more than 100 W. Speaker output connector 226 is coupled to and outputs the second audio output signal through the speakers, wherein the speakers can be home theater speakers with high output powers.

Note that speaker output connector 226 comprises 2 to 7.1 sound channels, wherein each sound channel can drive 10 to 100 W or more than 100 W.

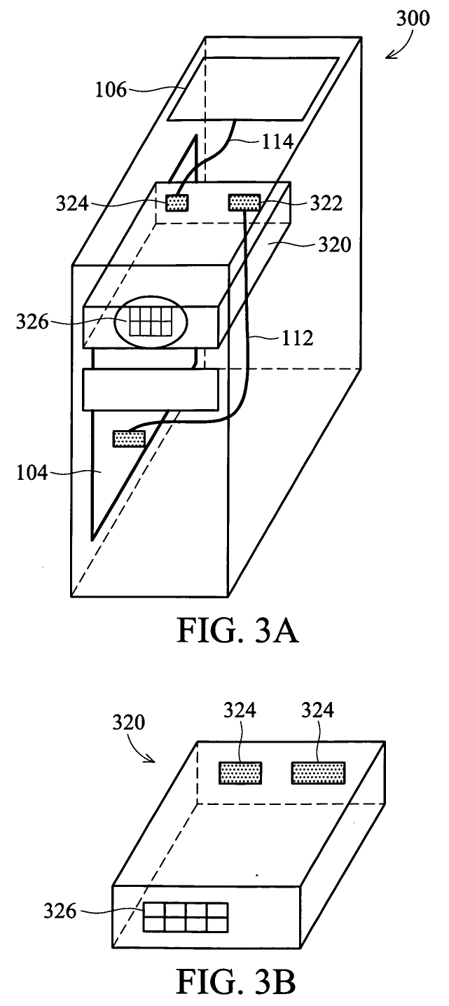

FIG. 3A is a schematic view of audio amplifier system 300 according to an embodiment of the invention. In this embodiment, audio amplifier module is implemented by audio amplifier module box. Audio-amplifier system 300 differs from audio-amplifier system 100 only in that the audio amplifier module box is compatible with bays for floppy disc drive, hard disc drive or optical disc drive.

FIG. 3B is a schematic view of audio amplifier module box 320 according to an embodiment of the invention. Audio amplifier module box 320 comprises voltage input connector 324, audio input signal connector 322, and speaker output connector 326.

Voltage input connector 324 is coupled to one of power lines 114 receiving 5V, 12V, and ground voltages from power supply 106 powering audio amplifier module box 320. Audio input signal connector 322 is coupled to audio output signal connector 110 via cable 112 receiving the first audio output signal. The amplifier circuit amplifies the first audio output signal into the second audio output signal. Audio input signal connector 322 can be an AC 97, high definition, Dolby, or digital theater system audio output signal connector, and the second audio output signal can be an AC 97, high definition, Dolby, or digital theater system audio output signal. The power of the amplifier circuit is between 10 and 100 W or more than 100 W. Speaker output connector 326 is coupled to the speakers and outputs the second audio output signal through the speakers, wherein the speakers can be home theater speakers with high output powers.

Note that speaker output connector 326 comprises 2 to 7.1 sound channels, wherein each sound channel can drive 10 to 100 W or more than 100 W.

The computer system with audio amplifier module 120, audio amplifier module card 220 or audio amplifier module box 320 can amplify the audio output signal through the amplifier circuit in audio amplifier module 120, audio amplifier module card 220 and audio amplifier module box 320 respectively for output by home theater speakers with high output power. By means of the audio amplifier system of the invention, video or music in a computer system can be played by home theater speakers without requiring additional audio amplifier to optimize the home theater experience and increase efficiency:

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An audio amplifier system, comprising:
a power supply having a plurality of power lines;
a mainboard, comprising:
a first voltage input connector coupled to one of the power lines receiving a first power supply; and
an audio output signal connector outputting a first audio output signal; and
an audio amplifier module disposed on a chassis, comprising:
a second voltage input connector coupled to one of the power lines receiving a second power supply;
an audio input signal connector coupled to the audio output signal connector via a cable receiving the first audio output signal; and
an amplifier circuit for amplifying the first audio output signal into a second audio output signal.

2. The audio amplifier system as claimed in claim 1, wherein the audio amplifier module further comprises a speaker output connector coupled to a speaker and the second audio output signal is output by the speaker.

3. The audio amplifier system as claimed in claim 1, wherein the power supply provides 5V, 12V, and ground voltage.

4. The audio amplifier system as claimed in claim 1, wherein the power lines are 4-pin power lines.

5. The audio amplifier system as claimed in claim 1, wherein the audio output signal connector is an AC 97, high definition, Dolby, or digital theater system audio output signal connector.

6. The audio amplifier system as claimed in claim 1, wherein the audio input signal connector is an AC 97, high definition, Dolby, or digital theater system audio input signal connector.

7. The audio amplifier system as claimed in claim 1, wherein the power of the amplifier circuit is between 10 and 100 W, or greater than 100 W.

8. The audio amplifier system as claimed in claim 1, wherein the speaker output connector comprises 2 to 7.1 sound channels, wherein each sound channel can drive between 10 and 100 W, or greater than 100 W.

9. The audio amplifier system as claimed in claim 1, wherein the speaker is a home theater speaker with high output power.

10. An audio amplifier system, comprising:
a power supply having a plurality of power lines;
a mainboard, comprising:
a first voltage input connector coupled to one of the power lines receiving a first power supply; and
an audio output signal connector outputting a first audio output signal; and
an audio amplifier module, comprising an audio amplifier module card or an audio amplifier module box, comprising:
a second voltage input connector coupled to another of the power lines receiving a second power supply;
an audio input signal connector coupled to the audio output signal connector via a cable receiving the first audio output signal; and
an amplifier circuit for amplifying the first audio output signal into a second audio output signal.

11. The audio amplifier system as claimed in claim. 10, wherein the audio amplifier module card is compatible with a peripheral controller interface, an accelerated graphics port, or a PCIE slot.

12. The audio amplifier system as claimed in claim 10, wherein the audio amplifier module box is compatible with bays for floppy disc drive, hard disc drive or optical disc drive.

13. The audio amplifier system as claimed in claim 10, wherein the audio amplifier module further comprises a speaker output connector coupled to a speaker and the second audio output signal is output by the speaker.

14. The audio amplifier system as claimed in claim 10, wherein the power supply provides 5V, 12V, and ground voltage.

15. The audio amplifier system as claimed in claim 10, wherein the power lines are 4-pin power lines.

16. The audio amplifier system as claimed in claim 10, wherein the audio output signal connector is an AC 97, high definition, Dolby, or digital theater system audio output signal connector.

17. The audio amplifier system as claimed in claim 10, wherein the audio input signal connector is an AC 97, high definition, Dolby, or digital theater system audio input signal connector.

18. The audio amplifier system as claimed in claim 10, wherein the power of the amplifier circuit is between 10 and 100 W, or greater than 100 W.

19. The audio amplifier system as claimed in claim 10, wherein the speaker output connector comprises 2 to 7.1 sound channels, wherein each sound channel can drive between 10 and 100 W, or greater than 100 W.

20. The audio amplifier system as claimed in claim 10, wherein the speaker is
a home theater speaker with high output power.
